(19) United States
(12) Patent Application Publication
(10) Pub. No.: US 2026/0051869 A1
(43) Pub. Date: Feb. 19, 2026

(54) PIEZOELECTRIC ELEMENT AND DRIVE DEVICE

(71) Applicant: TDK CORPORATION, Tokyo (JP)

(72) Inventors: Yuya SATO, Tokyo (JP); Katsuya IWAI, Tokyo (JP)

(73) Assignee: TDK CORPORATION, Tokyo (JP)

(21) Appl. No.: 19/250,647

(22) Filed: Jun. 26, 2025

(30) Foreign Application Priority Data
Jul. 25, 2024 (JP) 2024-119360

(51) Int. Cl. H03H 9/13; H03H 9/17

(52) U.S. Cl. CPC H03H 9/13; H03H 9/17

(57) ABSTRACT

An element body of a piezoelectric element contains a drive region in which a drive unit is disposed, the drive unit including a first internal electrode and a second internal electrode facing each other in a first direction with a piezoelectric layer interposed therebetween. The drive unit has a plurality of first drive units arranged in a third direction on one side in a second direction, and a plurality of second drive units arranged in the third direction on the other side in the second direction. In a case where the element body is viewed from the first direction, the first drive unit and the second drive unit are alternately disposed in the third direction.

### TECHNICAL FIELD

The present disclosure relates to a piezoelectric element and a drive device.

### BACKGROUND

As a conventional piezoelectric element, there is a piezoelectric element in which a plurality of drive units is arranged (see, for example, Japanese Unexamined Patent Publication No. 2010-98799). This conventional piezoelectric element is used as a power source for discharging droplets of ink or the like in a printing apparatus, and includes a pair of element bodies configured by a plurality of piezoelectric layers stacked in a first direction. The pair of element bodies is disposed on a base member at a predetermined interval.

Each element body has a predetermined width in a second direction orthogonal to the first direction and extends in a third direction orthogonal to the first direction and the second direction. In each element body, a first internal electrode and a second internal electrode face each other in the stacking direction with the piezoelectric layers interposed therebetween, thereby forming a drive unit that causes strain deformation. In each element body, the drive unit extends along the third direction, which is the extending direction of the element body.

### SUMMARY

In the conventional piezoelectric element as described above, since the plurality of drive units is disposed close to each other, interference in driving between the drive units becomes a problem. When the driving of the drive units interferes with each other, it is conceivable that the operation characteristics of the piezoelectric element vary.

The present disclosure has been made to solve the above problems, and an object thereof is to provide a piezoelectric element and a drive device capable of suppressing variations in operation characteristics.

The gist of the present disclosure is as follows.

[1] A piezoelectric element including: an element body configured by a plurality of piezoelectric layers stacked in a first direction, the element body having a predetermined width in a second direction orthogonal to the first direction and extending in a third direction orthogonal to the first direction and the second direction, in which the element body contains a drive region in which a drive unit is disposed, the drive unit including a first internal electrode and a second internal electrode facing each other in the first direction with the plurality of piezoelectric layers interposed between the first internal electrode and the second internal electrode, and the element body has a first external electrode electrically connected to the first internal electrode and a second external electrode electrically connected to the second internal electrode, the drive unit has a plurality of first drive units arranged in the third direction on one side in the second direction and a plurality of second drive units arranged in the third direction on another side in the second direction, and the plurality of first drive units and the plurality of second drive units are alternately disposed in the third direction in a case where the element body is viewed from the first direction.

In this piezoelectric element, the plurality of first drive units is arranged on the one side in the second direction of the element body, and the plurality of second drive units is arranged on the other side in the second direction of the element body. In addition, in a case where the element body is viewed from the first direction, the first drive unit and the second drive unit are alternately disposed in the third direction. According to this configuration, the drive units can be sufficiently separated from each other in the second direction and the third direction, and even in a case where the plurality of drive units is disposed in the drive region of the element body, it is possible to suppress interference in driving between the drive units. By suppressing interference in driving between the drive units, it is possible to suppress variations in the operation characteristics of the piezoelectric element.

[2] The piezoelectric element according to [1], in which the plurality of first drive units and the plurality of second drive units are disposed in a staggered manner in a case where the element body is viewed from the first direction. According to such a disposition configuration, the drive units can be more sufficiently separated in the second direction and the third direction. Therefore, it is possible to more effectively suppress interference in driving between the drive units.

[3] The piezoelectric element according to [1] or [2], in which the plurality of first drive units and the plurality of second drive units are separated in the second direction in a case where the element body is viewed from the third direction. According to such a disposition configuration, the drive units can be more sufficiently separated in the second direction. Therefore, it is possible to more effectively suppress interference in driving between the drive units.

[4] The piezoelectric element according to any one of [1] to [3], in which a non-drive region in which neither the plurality of first drive units nor the plurality of second drive units is disposed is provided at an end part in the third direction of the element body, and a dummy electrode formed by the first internal electrode or the second internal electrode is disposed in the non-drive region. In this case, the thickness of the element body in the first direction in the drive region and the thickness of the element body in the first direction in the non-drive region can be made uniform.

[5] A drive device including: the piezoelectric element according to any one of [1] to [4]; and a wiring part electrically connected to the first external electrode and the second external electrode. In the drive device, by using the above-described piezoelectric element, it is possible to take out an output to the outside in a state where variations in operation characteristics are suppressed.

[6] The drive device according to [5], in which the element body has a plurality of bottomed first recesses extending in the second direction, and the plurality of first drive units and the plurality of second drive units alternately disposed in the third direction are partitioned by the plurality of bottomed first recesses. In this case, the first drive unit and the second drive unit can be physically separated from each other in the third direction by the first recess. Therefore, it is possible to more effectively suppress interference in driving between the drive units. In addition, since the first recess is bottomed, displacement of the element body can be restrained at the bottom part of the first recess.

[7] The drive device according to [6], in which in the element body, an element body portion partitioned by the plurality of bottomed first recesses is continuous in the second direction. By providing the element body portion continuous in the second direction, it is possible to suitably avoid interlocking between driving of the first drive unit and driving of the second drive unit.

[8] The drive device according to [6], in which in the element body, an element body portion partitioned by the plurality of bottomed first recesses is partitioned by a bottomed second recess extending in the third direction into a first element body portion in which one of the plurality of first drive units is located and a second element body portion in which one of the plurality of second drive units is located. In this case, the first drive unit and the second drive unit can be physically separated in both the second direction and the third direction by the first recesses and the second recess. Therefore, it is possible to more effectively suppress interference in driving between the drive units. In addition, since the second recess is bottomed, the displacement of the element body can be restrained at the bottom part of the second recess.

[9] The drive device according to [8], in which the first external electrode electrically connected to the first internal electrode of one of the plurality of first drive units is located on one end surface in the second direction of the element body, the first external electrode electrically connected to the first internal electrode of one of the plurality of second drive units is located on another end surface in the second direction of the element body, and the second external electrode electrically connected to a plurality of the second internal electrode of the plurality of first drive units and a plurality of the second internal electrode of the plurality of second drive units is located on an inner wall surface of the bottomed second recess and an end surface in the first direction of the element body continuous with the inner wall surface. According to such a configuration, even in a case where the first drive unit and the second drive unit are physically separated in both the second direction and the third direction by the first recesses and the second recess, the wiring part can be connected to the first external electrode and the second external electrode with a simple configuration.

[10] The drive device according to any one of [5] to [9], further including a base substrate electrically connected to the second external electrode. In this case, the strength of the piezoelectric element can be secured by the base substrate. In addition, by electrically connecting the base substrate to the piezoelectric element via the second external electrode, the base substrate can be used as a ground potential of the piezoelectric element. Thus, driving of the piezoelectric element is stabilized.

### BRIEF DESCRIPTION OF THE DRAWINGS

FIG. 1 is a perspective view of a drive device according to a first embodiment of the present disclosure;

FIG. 2 is a cross-sectional view taken along line II-II in FIG. 1;

FIG. 3 is a cross-sectional view taken along line III-III in FIG. 1;

FIG. 4 is a cross-sectional view taken along line IV-IV in FIG. 1;

FIG. 5A is a plan view illustrating an example of a pattern of a first internal electrode;

FIG. 5B is a plan view illustrating an example of a pattern of a second internal electrode;

FIG. 6A is a plan view illustrating another example of the pattern of the first internal electrode;

FIG. 6B is a plan view illustrating another example of the pattern of the second internal electrode;

FIG. 7 is a perspective view of a drive device according to a second embodiment of the present disclosure;

FIG. 8 is a cross-sectional view taken along line VIII-VIII in FIG. 7;

FIG. 9 is a cross-sectional view taken along line IX-IX in FIG. 7;

FIG. 10 is a cross-sectional view taken along line X-X in FIG. 7;

FIG. 11A is a plan view illustrating an example of a pattern of a first internal electrode; and

FIG. 11B is a plan view illustrating an example of a pattern of a second internal electrode.

### DETAILED DESCRIPTION

Hereinafter, preferred embodiments of a piezoelectric element and a drive device according to one aspect of the present disclosure will be described in detail with reference to the drawings.

### First Embodiment

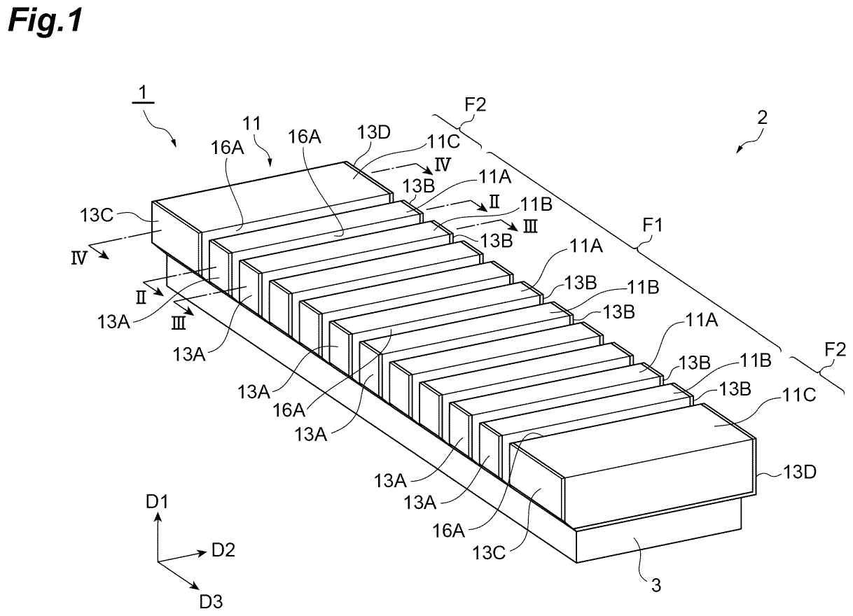

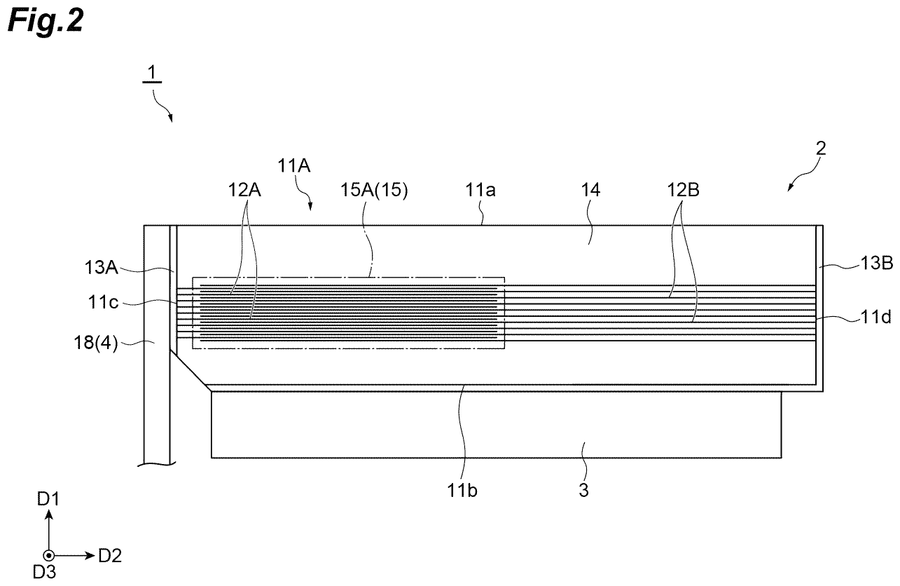

FIG. 1 is a perspective view of a drive device according to a first embodiment of the present disclosure. The drive device 1 illustrated in FIG. 1 is a device used as a power source for discharging droplets of ink or the like in a printing machine, for example. As illustrated in FIG. 1, the drive device 1 is configured by including a piezoelectric element 2, a base substrate 3, and a wiring part 4 (see FIG. 2 and the like).

The piezoelectric element 2 includes an element body 11 having a substantially rectangular parallelepiped shape, a plurality of internal electrodes (first internal electrodes 12A and second internal electrodes 12B), and a plurality of external electrodes (first external electrodes 13A, second external electrodes 13B, third external electrodes 13C, and fourth external electrodes 13D). The element body 11 is formed in a flat substantially rectangular parallelepiped shape by a plurality of piezoelectric layers 14 (see FIG. 2 and the like) stacked in a first direction D1. The element body 11 has a predetermined width in a second direction D2 orthogonal to the first direction D1 and extends in a third direction D3 orthogonal to the first direction D1 and the second direction D2.

In the present embodiment, the element body 11 is configured by a piezoelectric ceramic material. Examples of the piezoelectric ceramic material include those containing lead zirconate titanate (PZT:Pb(Zrₓ, Ti₁₋ₓ)O₃) as a main component. Each piezoelectric layer 14 is configured by, for example, a sintered body of a ceramic green sheet containing the above-described piezoelectric ceramic material. In the element body 11, the piezoelectric layers 14 are integrated to such an extent that boundaries between the piezoelectric layers cannot be recognized.

The first internal electrode 12A and the second internal electrode 12B are formed by, for example, a conductive material containing silver and palladium as main components. The conductive material may be copper. The first internal electrode 12A and the second internal electrode 12B are, for example, sintered bodies of a conductive paste containing a conductive material. The first external electrode 13A, the second external electrode 13B, and the third external electrode 13C are formed by a plurality of metal films made of, for example, chromium, copper/nickel, or gold. Instead of the metal film made of gold, a metal film made of silver, a metal film made of a silver-palladium alloy, a metal film made of a silver-tin alloy, or the like may be used.

The element body 11 has a drive region F1 that is driven in a case where a voltage is applied to the piezoelectric element 2 and a non-drive region F2 that is not driven in a case where a voltage is applied to the piezoelectric element 2. In the present embodiment, as illustrated in FIG. 1, both end parts in the third direction D3 of the element body 11 serve as the non-drive regions F2, and the drive region F1 is disposed so as to be sandwiched by the non-drive regions F2.

The drive region F1 is a region where the drive units 15 (the first drive units 15A and the second drive units 15B) in which the first internal electrode 12A and the second internal electrode 12B face each other in the first direction with the piezoelectric layers 14 interposed therebetween are disposed. In the present embodiment, in the drive region F1, an element body portion 11A in which the first drive unit 15A is provided and an element body portion 11B in which the second drive unit 15B is provided are alternately arranged in the third direction D3.

The element body portion 11A and the element body portion 11B are partitioned by a bottomed first recess 16A extending in the second direction D2. In the present embodiment, a direction from an end surface 11a of the element body 11 on a side opposite to the base substrate 3 in the first direction D1 toward an end surface 11b of the element body 11 on the base substrate 3 side in the first direction D1 is defined as a depth direction in the first recess 16A. The cross-sectional shape of the first recess 16A viewed from the second direction D2 is, for example, a rectangular shape. The first recess 16A divides the first internal electrodes 12A and the second internal electrodes 12B contained in the element body portion 11A and the first internal electrodes 12A and the second internal electrodes 12B contained in the element body portion 11B in the third direction D3. Each of the element body portion 11A and the element body portion 11B partitioned by the first recess 16A is continuous in the second direction D2.

In the present embodiment, the first recess 16A is also formed between the non-drive region F2 on one side in the third direction D3 and the element body portion 11A and between the non-drive region F2 on the other side in the third direction D3 and the element body portion 11B. The first recess 16A divides the internal electrodes (here, the second internal electrodes 12B) contained in the non-drive region F2 on one side in the third direction D3 and the first internal electrodes 12A and the second internal electrodes 12B contained in the element body portion 11A in the third direction D3. In addition, the first recess 16A divides the internal electrodes (here, the second internal electrodes 12B) contained in the non-drive region F2 on the other side in the third direction D3 and the first internal electrodes 12A and the second internal electrodes 12B contained in the element body portion 11B in the third direction D3.

As illustrated in FIG. 2, the element body portion 11A contains only the first drive unit 15A. In the first drive unit 15A, the first internal electrode 12A extending from one end surface 11c toward the other end surface 11d in the second direction D2 of the element body 11 and the second internal electrode 12B extending from the other end surface 11d toward the one end surface 11c in the second direction D2 of the element body 11 face each other in the first direction D1 with the piezoelectric layers 14 interposed therebetween on one side in the second direction D2 (on the one end surface 11c side with respect to the center of the element body 11 in the second direction D2).

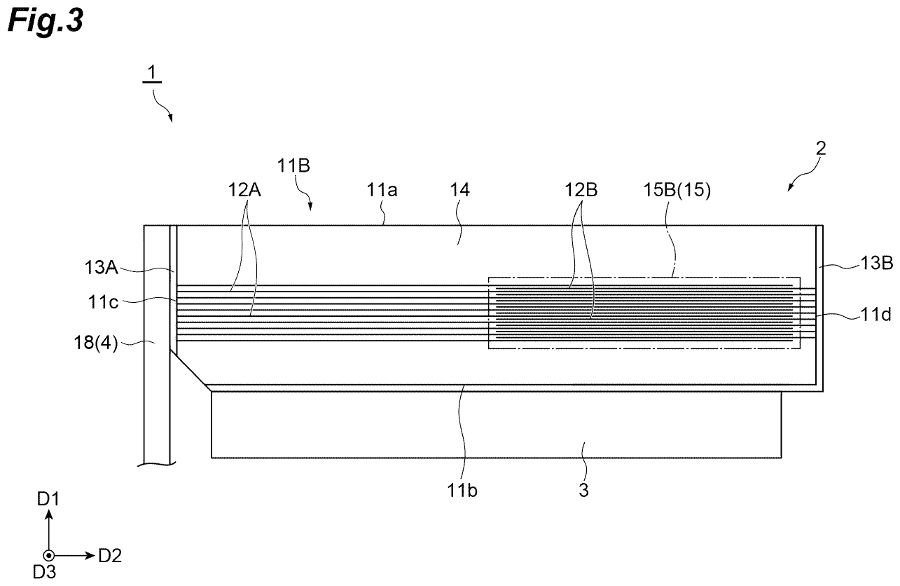

As illustrated in FIG. 3, the element body portion 11B contains only the second drive unit 15B. In the second drive unit 15B, the first internal electrode 12A extending from the one end surface 11c toward the other end surface 11d in the second direction D2 of the element body 11 and the second internal electrode 12B extending from the other end surface 11d toward the one end surface 11c in the second direction D2 of the element body 11 face each other in the first direction D1 with the piezoelectric layers 14 interposed therebetween on the other side in the second direction D2 (on the other end surface 11d side with respect to the center of the element body 11 in the second direction D2).

With the above-described configuration, in the drive region F1, the plurality of first drive units 15A is arranged in the third direction D3 on one side in the second direction D2, and the plurality of second drive units 15B is arranged in the third direction D3 on the other side in the second direction D2. Since the element body portion 11A in which the first drive unit 15A is provided and the element body portion 11B in which the second drive unit 15B is provided are alternately arranged in the third direction D3, the first drive unit 15A and the second drive unit 15B are alternately arranged in the third direction D3 in a case where the element body 11 is viewed from the first direction D1.

In the present embodiment, in a case where the element body 11 is viewed from the first direction D1, the first drive units 15A and the second drive units 15B are disposed in a staggered manner. In addition, the first drive unit 15A and the second drive unit 15B are positioned on the one end surface 11c side and the other end surface 11d side, respectively, with the center of the element body 11 in the second direction D2 interposed therebetween, and are in a state of being separated in the second direction D2 in a case where the element body 11 is viewed from the third direction D3.

The non-drive region F2 is a region where the drive unit 15 (the first drive unit 15A and the second drive unit 15B) in which the first internal electrode 12A and the second internal electrode 12B face each other in the first direction with the piezoelectric layers 14 interposed therebetween is not disposed. In the present embodiment, the non-drive region F2 is configured by an element body portion 11C having neither the first drive unit 15A nor the second drive unit 15B.

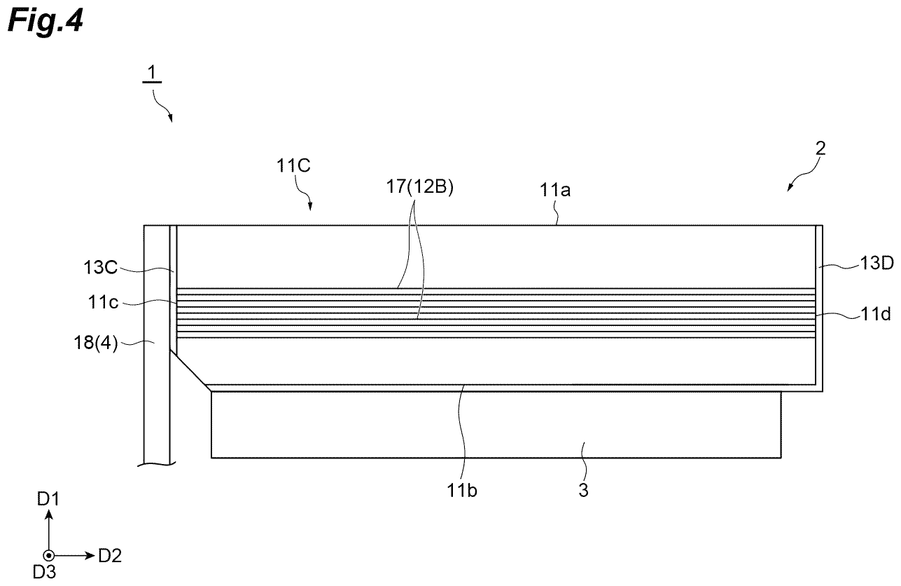

In the element body portion 11C, as illustrated in FIG. 4, dummy electrodes 17 formed by the first internal electrodes 12A or the second internal electrodes 12B are disposed. In the example of FIG. 4, the dummy electrodes 17 formed by the second internal electrodes 12B are disposed. The second internal electrodes 12B constituting the dummy electrodes 17 in the element body portion 11C extend at the same positions in the first direction D1 as the second internal electrodes 12B of the element body portions 11A, 11B so as to connect the one end surface 11c and the other end surface 11d in the second direction D2 of the element body 11.

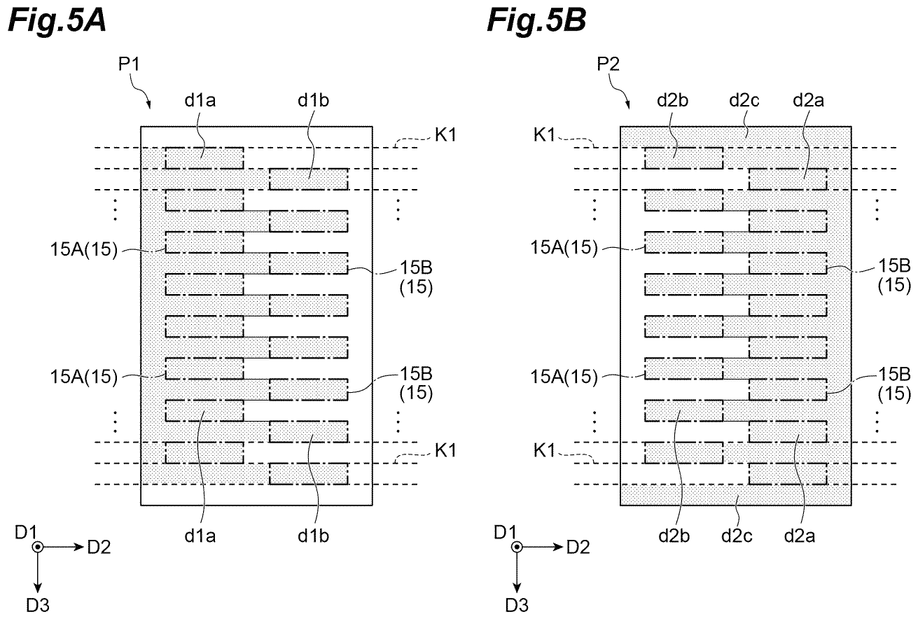

FIG. 5A is a plan view illustrating an example of a pattern of the first internal electrode, and FIG. 5B is a plan view illustrating an example of a pattern of the second internal electrode. As illustrated in FIG. 5A, a pattern P1 of the first internal electrode 12A has an electrode portion d1a extending just before the center from the one end surface 11c in the second direction D2 of the element body 11, and an electrode portion d1b extending from the one end surface 11c in the second direction D2 of the element body 11 to the other end surface 11d side beyond the center. The electrode portion d1a and the electrode portion d1b are alternately arranged in the third direction.

As illustrated in FIG. 5B, a pattern P2 of the second internal electrode 12B has an electrode portion d2a extending just before the center from the other end surface 11d in the second direction D2 of the element body 11, and an electrode portion d2b extending from the other end surface 11d in the second direction D2 of the element body 11 to the one end surface 11c side beyond the center. The electrode portion d2a and the electrode portion d2b are alternately arranged in the third direction. The arrangement order of the electrode portions d2a and the electrode portions d2b in the third direction D3 is reversed from the arrangement order of the electrode portions d1a and the electrode portions d1b in the third direction D3. Electrode portions d2c connecting the one end surface 11c and the other end surface 11d in the second direction D2 of the element body 11 are arranged at both ends in the third direction D3.

By alternately stacking the pattern P1 of the first internal electrode 12A and the pattern P2 of the second internal electrode 12B in the first direction D1 with the piezoelectric layers 14 interposed therebetween to form the element body 11, in the drive region F1, the first drive unit 15A is formed by the electrode portion d1a and the electrode portion d2b facing each other with the piezoelectric layers 14 interposed therebetween, and the second drive unit 15B is formed by the electrode portion d1b and the electrode portion d2a facing each other with the piezoelectric layers 14 interposed therebetween. In the non-drive region F2, the dummy electrode 17 is formed by the electrode portion d2c.

The bottomed first recess 16a extending in the second direction D2 is formed along a processing line K1 in the formed element body 11. As a result, the element body 11 is partitioned into the element body portion 11A having the first drive unit 15A, the element body portion 11B having the second drive unit 15B, and the element body portion 11C having the dummy electrode 17, and the drive region F1 and the non-drive region F2 described above are formed in the element body 11.

As illustrated in FIG. 1, the plurality of external electrodes is configured by the first external electrodes 13A electrically connected to the first internal electrodes 12A, the second external electrodes 13B electrically connected to the second internal electrodes 12B, and the third external electrodes 13C and the fourth external electrodes 13D connected to the dummy electrodes 17. The first external electrode 13A is, for example, a positive electrode. As illustrated in FIGS. 2 and 3, in each of the element body portion 11A and the element body portion 11B belonging to the drive region F1, the first external electrode 13A is disposed on the entire surface of the one end surface 11c in the second direction D2 of the element body 11, and is electrically connected to the first internal electrodes 12A on the one end surface 11c.

The second external electrode 13B is, for example, a negative electrode. As illustrated in FIGS. 2 and 3, the second external electrode 13B is disposed on the entire surface of the end surface 11b on the base substrate 3 side in the first direction D1 of the element body 11 in a state of being separated from the first external electrode 13A in the drive region F1. In each of the element body portion 11A and the element body portion 11B, the second external electrode 13B is disposed on the entire surface of the other end surface 11d in the second direction D2 of the element body 11, and is electrically connected to the second internal electrodes 12B on the other end surface 11d.

As illustrated in FIG. 4, in the element body portion 11C belonging to the non-drive region F2, the third external electrode 13C is disposed on the entire surface of the one end surface 11c in the second direction D2 of the element body 11, and is electrically connected to the second internal electrodes 12B on the one end surface 11c. As illustrated in FIG. 4, the fourth external electrode 13D is disposed on the entire surface of the end surface 11b on the base substrate 3 side in the first direction D1 of the element body 11 in a state of being separated from the third external electrode 13C in the non-drive region F2. The fourth external electrode 13D is continuous with the second external electrode 13B on the end surface 11b. In addition, in the element body portion 11C, the fourth external electrode 13D is disposed on the entire surface of the other end surface 11d in the second direction D2 of the element body 11, and is electrically connected to the second internal electrodes 12B on the other end surface 11d.

The base substrate 3 is a member that holds the piezoelectric element 2, and the base substrate 3 is configured by metal, for example, and has a flat substantially rectangular parallelepiped shape corresponding to the shape of the piezoelectric element 2. Examples of the metal material constituting the base substrate 3 include metals such as SUS. The base substrate 3 is electrically connected to the second external electrodes 13B. In the present embodiment, an electrode pad, not illustrated, is provided on the base substrate 3. The base substrate 3 is electrically connected to the second external electrode 13B and the fourth external electrode 13D via the electrode pad.

The wiring part 4 is configured by, for example, a flexible printed circuit board 18. In the present embodiment, as illustrated in FIGS. 2 to 4, the flexible printed circuit board 18 is disposed only on the one end surface 11c side in the second direction D2 in the element body 11. The flexible printed circuit board 18 is electrically connected to each of the first external electrode 13A and the third external electrode 13C located on the one end surface 11c in the second direction D2 of the element body 11.

In the drive device 1, voltages having different polarities are applied to the first external electrode 13A and the second external electrode 13B via the base substrate 3 and the flexible printed circuit board 18, so that the drive unit 15 belonging to the drive region F1 can be distorted and deformed. By applying different potential differences to the first drive unit 15A and the second drive unit 15B via the base substrate 3 and the flexible printed circuit board 18, each of the first drive unit 15A and the second drive unit 15B can be independently driven.

As described above, in the piezoelectric element 2, the plurality of first drive units 15A is arranged on the one side in the second direction D2 of the element body 11, and the plurality of second drive units 15B is arranged on the other side in the second direction D2 of the element body 11. In addition, in a case where the element body 11 is viewed from the first direction D1, the first drive unit 15A and the second drive unit 15B are alternately disposed in the third direction D3. According to this configuration, the drive units 15 can be sufficiently separated from each other in the second direction D2 and the third direction D3, and even in a case where the plurality of drive units 15 is disposed in the drive region F1 of the element body 11, it is possible to suppress interference in driving between the drive units 15. By suppressing interference in driving between the drive units 15, it is possible to suppress variations in the operation characteristics of the piezoelectric element 2.

In the present embodiment, in a case where the element body 11 is viewed from the first direction D1, the first drive units 15A and the second drive units 15B are disposed in a staggered manner. In addition, in a case where the element body 11 is viewed from the third direction D3, the first drive unit 15A and the second drive unit 15B are separated in the second direction D2. According to such a disposition configuration, the drive units 15 can be more sufficiently separated in the second direction D2 and the third direction D3. Therefore, it is possible to more effectively suppress interference in driving between the drive units 15.

In the present embodiment, the non-drive regions F2 in which neither the first drive unit 15A nor the second drive unit 15B is disposed are provided at the end parts in the third direction D3 of the element body 11, and the dummy electrodes 17 formed by the first internal electrodes 12A or the second internal electrodes 12B (in the present embodiment, the second internal electrodes 12B) are disposed in the non-drive region F2. In this case, the thickness of the element body 11 in the first direction D1 in the drive region F1 and the thickness of the element body 11 in the first direction D1 in the non-drive region F2 can be made uniform. By making the thickness in the first direction D1 of the element body 11 uniform in the drive region F1 and the non-drive region F2, it is possible to suppress application of unnecessary stress to the element body 11 at the time of driving the piezoelectric element 2 or the like.

In addition, the drive device 1 includes the above-described piezoelectric element 2, and the wiring part 4 electrically connected to the first external electrodes 13A and the third external electrodes 13C. In the drive device 1, by using the above-described piezoelectric element 2, it is possible to take out an output to the outside in a state where variations in operation characteristics are suppressed.

In the present embodiment, the element body 11 has the plurality of bottomed first recesses 16A extending in the second direction D2. The first drive unit 15A and the second drive unit 15B alternately arranged in the third direction D3 are partitioned by the first recess 16A. By providing such a first recess 16A in the element body 11, the first drive unit 15A and the second drive unit 15B can be physically separated in the third direction D3. Therefore, it is possible to more effectively suppress interference in driving between the drive units 15. In addition, since the first recess 16A is bottomed, displacement of the element body 11 can be restrained at the bottom part of the first recess 16A.

In the present embodiment, in the element body 11, each of the element body portion 11A and the element body portion 11B partitioned by the first recess 16A is continuous in the second direction D2. By providing the element body portion continuous in the second direction D2, it is possible to suitably avoid interlocking between driving of the first drive unit 15A and driving of the second drive unit 15B.

In the present embodiment, the drive device 1 includes the base substrate 3 electrically connected to the second external electrodes 13B. In this case, strength of the piezoelectric element 2 can be secured by the base substrate 3. In addition, by electrically connecting the base substrate 3 to the piezoelectric element 2 via the second external electrodes 13B, the base substrate 3 can be used as a ground potential of the piezoelectric element 2. Thus, driving of the piezoelectric element 2 is stabilized.

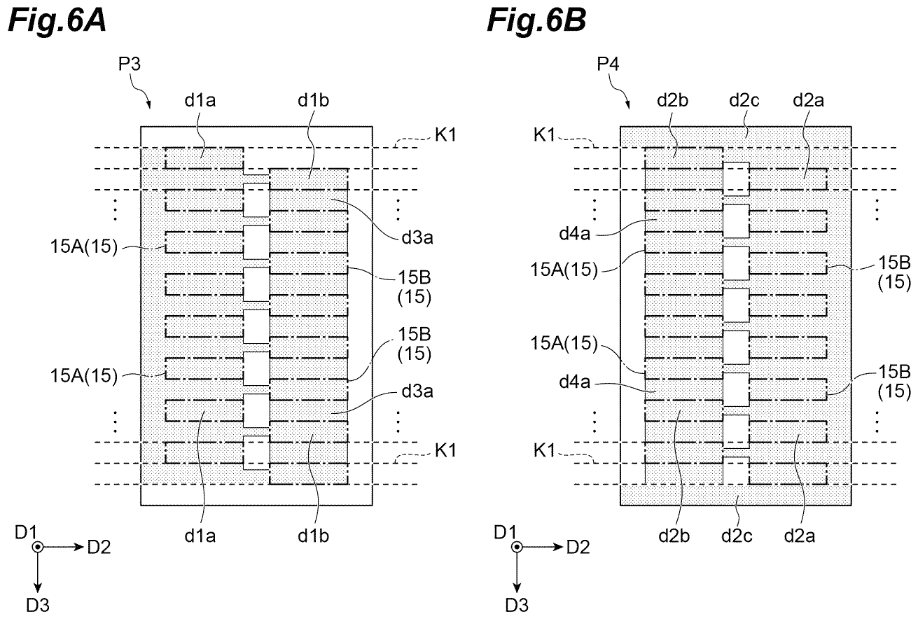

FIG. 6A is a plan view illustrating another example of the pattern of the first internal electrode, and FIG. 6B is a plan view illustrating another example of the pattern of the second internal electrode. As illustrated in FIG. 6A, a pattern P3 of the first internal electrode 12A is different from the pattern P1 of the first internal electrode 12A illustrated in FIG. 5A in that, in the electrode portions d1b adjacent to each other in the third direction D3, front ends on the other end surface 11d side with respect to the center in the second direction D2 are connected by an electrode portion d3a. In addition, in the electrode portion d1b, the width of the central portion in the second direction D2 is smaller than the widths of the other portions.

As illustrated in FIG. 6B, a pattern P4 of the second internal electrode 12B is different from the pattern P2 of the second internal electrode 12B illustrated in FIG. 5B in that, in the electrode portions d2b adjacent to each other in the third direction D3, front ends on the one end surface 11c side from the center in the second direction D2 are connected by the electrode portion d4a. In addition, in the electrode portion d2b, the width of the central portion in the second direction D2 is smaller than the widths of the other portions.

Even in a case where the element body 11 is formed by alternately stacking the pattern P3 of the first internal electrode 12A and the pattern P4 of the second internal electrode 12B in the first direction D1 with the piezoelectric layers 14 interposed therebetween, in the drive region F1, the first drive unit 15A is formed by the electrode portion d1a and the electrode portion d2b facing each other with the piezoelectric layers 14 interposed therebetween, and the second drive unit 15B is formed by the electrode portion d1b and the electrode portion d2a facing each other with the piezoelectric layers 14 interposed therebetween. In the non-drive region F2, the dummy electrode 17 is formed by the electrode portion d2c.

Note that in a case where the pattern P3 of the first internal electrode 12A and the pattern P4 of the second internal electrode 12B are used, a facing portion in which the base end portion of the electrode portion d2b and the electrode portion d3a face each other with the piezoelectric layers 14 interposed therebetween is formed on the other end surface 11d side in the second direction D2 in the element body portion 11A, and a facing portion in which the base end portion of the electrode portion d1b and the electrode portion d4a face each other with the piezoelectric layers 14 interposed therebetween is formed on the one end surface 11c side in the second direction D2 in the element body portion 11B. These facing portions become dummy drive units physically separated from the first drive unit 15A, the second drive unit 15B, the first external electrode 13A, and the second external electrode 13B by providing the first recesses 16A in the element body 11.

By disposing such dummy drive units, in the element body portion 11A and the element body portion 11B, the thickness in the first direction D1 on the one end surface 11c side in the second direction D2 and the thickness in the first direction D1 on the other end surface 11d side in the second direction D2 can be made uniform. By making the thicknesses uniform, it is possible to suppress application of unnecessary stress to the element body 11 at the time of driving the piezoelectric element 2 or the like.

### Second Embodiment

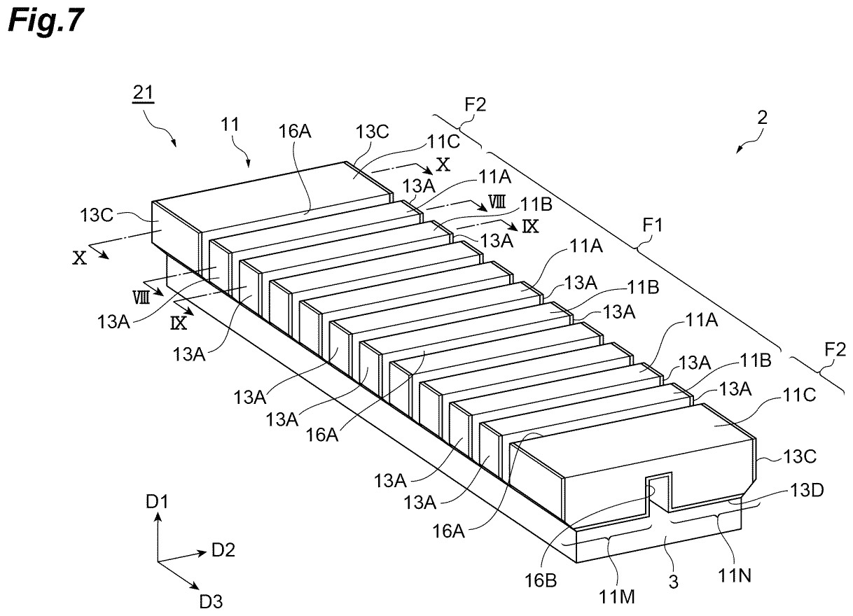

FIG. 7 is a perspective view of a drive device according to a second embodiment of the present disclosure. As illustrated in FIG. 7, a drive device 21 according to the second embodiment is different from that of the first embodiment in that, in a piezoelectric element 2, element body portions 11A, 11B partitioned by a first recess 16A are further partitioned by a bottomed second recess 16B extending in a third direction D3. Accordingly, the configurations of a first external electrode 13A, a second external electrode 13B, a third external electrode 13C, a fourth external electrode 13D, and a wiring part 4 are different from those of the first embodiment.

In the present embodiment, a direction from an end surface 11b of the element body 11 on a base substrate 3 side in a first direction D1 toward an end surface 11a of the element body 11 on a side opposite to the base substrate 3 side in the first direction D1 is defined as a depth direction in the second recess 16B. The cross-sectional shape of the second recess 16B viewed from the third direction D3 is, for example, a rectangular shape. The second recess 16B divides the element body 11 in the width direction at the center in a second direction D2. As a result, each of the element body portion 11A, the element body portion 11B, and an element body portion 11C partitioned by the first recesses 16A is in a state of being partitioned into a first element body portion 11M on a one end surface 11c side in which a first drive unit 15A is located and a second element body portion 11N on the other end surface 11d side in which a second drive unit 15B is located.

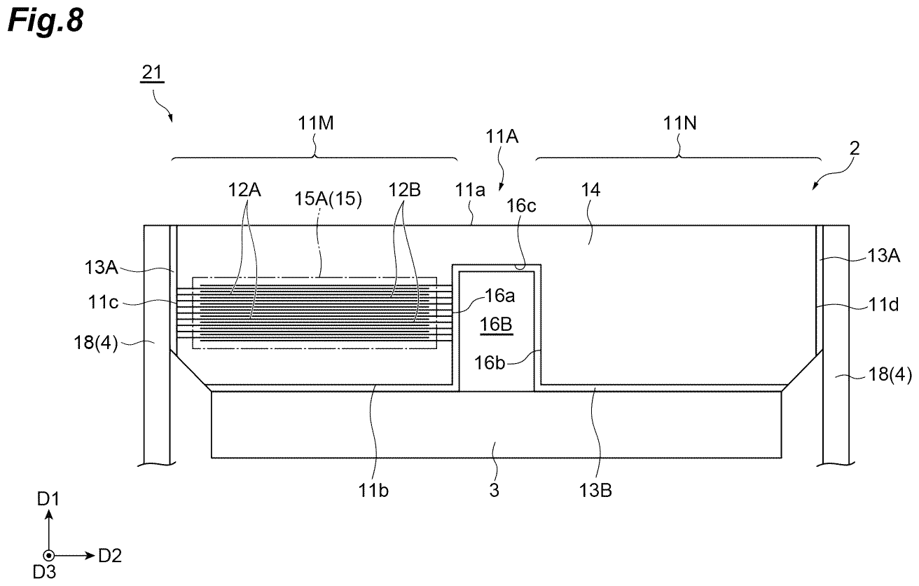

As illustrated in FIG. 8, in the element body portion 11A, only the first drive unit 15A is contained in the first element body portion 11M. In the first drive unit 15A, a first internal electrode 12A extending from one end surface 11c in the second direction D2 of the element body 11 toward a first inner wall surface (inner wall surface on the one end surface 11c side) 16a of the second recess 16B and a second internal electrode 12B extending from the first inner wall surface 16a of the second recess 16B toward the one end surface 11c in the second direction D2 of the element body 11 face each other in the first direction D1 with a piezoelectric layers 14 interposed therebetween.

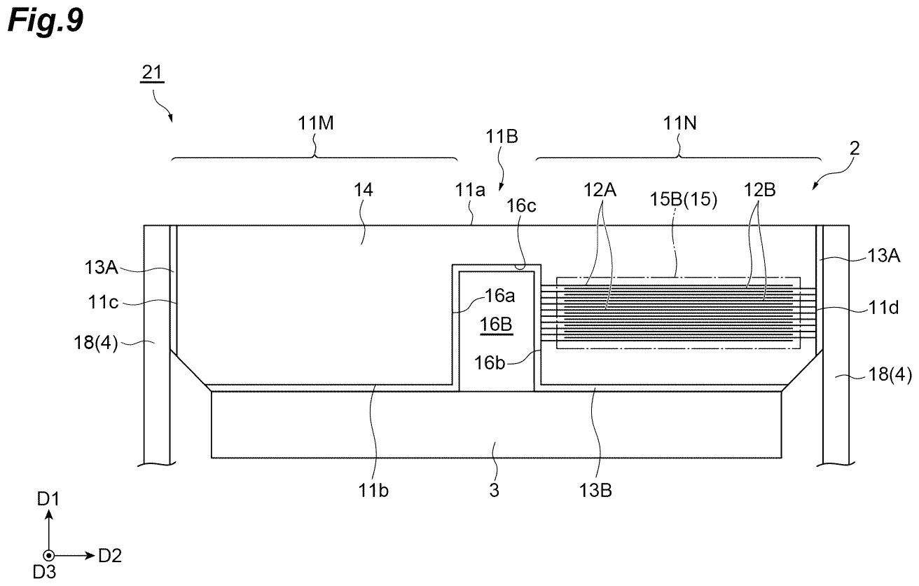

As illustrated in FIG. 9, in the element body portion 11B, only the second drive unit 15B is contained in the second element body portion 11N. In the second drive unit 15B, the first internal electrode 12A extending from the other end surface 11d in the second direction D2 of the element body 11 toward a second inner wall surface (inner wall surface on the other end surface 11d side) 16b of the second recess 16B and the second internal electrode 12B extending from the second inner wall surface 16b of the second recess 16B toward the other end surface 11d in the second direction D2 of the element body 11 face each other in the first direction D1 with the piezoelectric layers 14 interposed therebetween on the other end surface 11d side with respect to the second recess 16B.

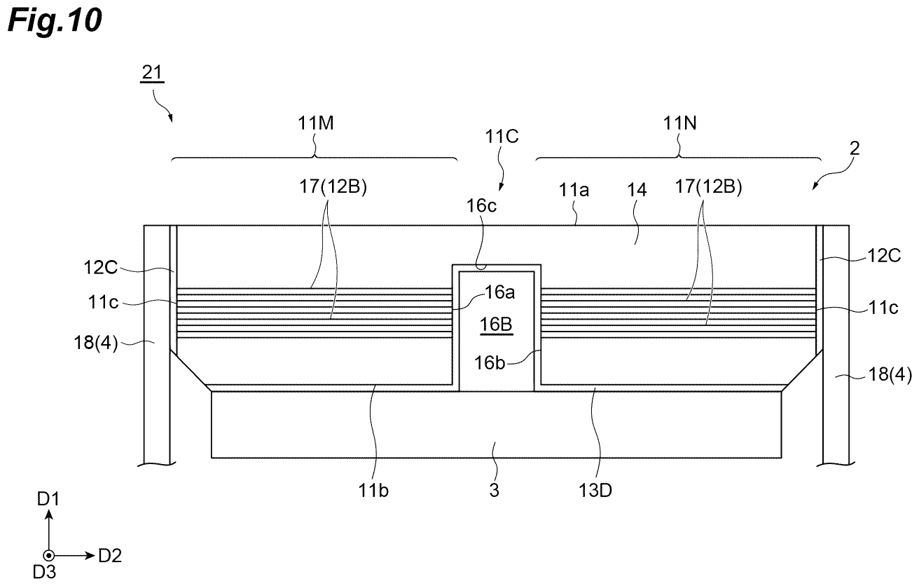

In the element body portion 11C, as illustrated in FIG. 10, dummy electrodes 17 formed by the first internal electrodes 12A or the second internal electrodes 12B are disposed in both the first element body portion 11M and the second element body portion 11N. In the example of FIG. 10, the dummy electrodes 17 formed by the second internal electrodes 12B are disposed. The second internal electrodes 12B constituting the dummy electrodes 17 in the first element body portion 11M extend at the same positions in the first direction D1 as the second internal electrodes 12B of the element body portions 11A, 11B so as to connect the one end surface 11c in the second direction D2 of the element body 11 and the first inner wall surface 16a of the second recess 16B. The second internal electrodes 12B constituting the dummy electrodes 17 in the second element body portion 11N extend at the same positions in the first direction D1 as the second internal electrodes 12B of the element body portions 11A, 11B so as to connect the other end surface 11d in the second direction D2 of the element body 11 and the second inner wall surface 16b of the second recess 16B.

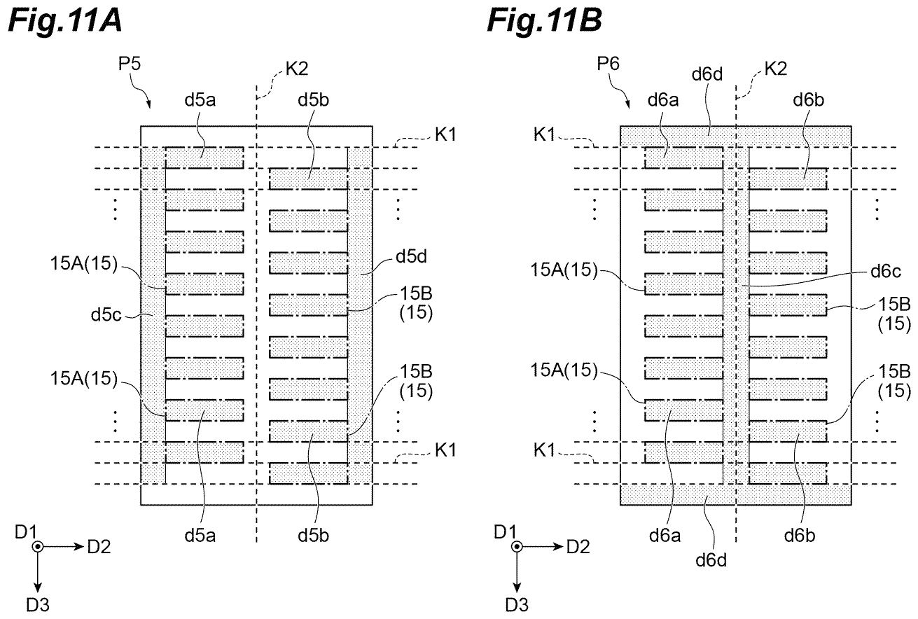

FIG. 11A is a plan view illustrating an example of a pattern of the first internal electrode, and FIG. 11B is a plan view illustrating an example of a pattern of the second internal electrode. As illustrated in FIG. 11A, a pattern P5 of the first internal electrode 12A has an electrode portion d5a extending just before the center from the one end surface 11c in the second direction D2 of the element body 11, and an electrode portion d5b extending just before the center from the other end surface 11d of the element body 11 in the second direction D2. The electrode portion d5a and the electrode portion d5b are alternately arranged in the third direction. The base end parts of the electrode portions d5a are connected by an electrode portion d5c extending in the third direction D3 along the one end surface 11c, and the base end parts of the electrode portions d5b are connected by an electrode portion d5d extending in the third direction D3 along the other end surface 11d.

As illustrated in FIG. 11B, a pattern P6 of the second internal electrode 12B has an electrode portion d6a extending just before the one end surface 11c from the center in the second direction D2 of the element body 11, and an electrode portion d6b extending just before the other end surface 11d from the center in the second direction D2 of the element body 11. The electrode portion d6a and the electrode portion d6b are alternately arranged in the third direction. The base end parts of the electrode portions d6a, d6a are connected by an electrode portion d6c extending in the third direction D3 at the center in the second direction D2 of the element body 11. Electrode portions d6d connecting the one end surface 11c and the other end surface 11d in the second direction D2 of the element body 11 are disposed at both ends in the third direction D3.

By alternately stacking the pattern P5 of the first internal electrode 12A and the pattern P6 of the second internal electrode 12B in the first direction D1 with the piezoelectric layers 14 interposed therebetween to form the element body 11, in a drive region F1, the first drive unit 15A is formed by the electrode portion d5a and the electrode portion d6a facing each other with the piezoelectric layers 14 interposed therebetween, and the second drive unit 15B is formed by the electrode portion d5b and the electrode portion d6b facing each other with the piezoelectric layers 14 interposed therebetween. In a non-drive region F2, the dummy electrode 17 is formed by the electrode portion d6d.

The bottomed first recess 16A extending in the second direction D2 is formed along a processing line K1 in the formed element body 11. As a result, the element body 11 is partitioned into the element body portion 11A having the first drive unit 15A, the element body portion 11B having the second drive unit 15B, and the element body portion 11C having the dummy electrodes 17. In addition, the bottomed second recess 16B extending in the third direction D3 is formed along a processing line K2 in the formed element body 11. As a result, the element body 11 is partitioned into the first element body portion 11M in which the first drive unit 15A is located and the second element body portion 11N in which the second drive unit 15B is located, and the drive region F1 and the non-drive region F2 described above are formed in the element body 11.

In the present embodiment, as illustrated in FIGS. 8 and 9, the first external electrode 13A is disposed on each of the one end surface 11c and the other end surface 11d in the second direction D2 of the element body 11. Specifically, the first external electrode 13A electrically connected to the first internal electrodes 12A of the first drive unit 15A is located on the one end surface 11c in the second direction D2 of the element body 11, and the first external electrode 13A electrically connected to the first internal electrodes 12A of the second drive unit 15B is located on the other end surface 11d in the second direction D2 of the element body 11.

In contrast, the second external electrode 13B is a common electrode of the first drive unit 15A and the second drive unit 15B. As illustrated in FIGS. 8 and 9, the second external electrode 13B is disposed on the entire surface of the end surface 11b on the base substrate 3 side in the first direction D1 of the element body 11 and the entire surface of the inner wall surface (the first inner wall surface 16a, the second inner wall surface 16b, and a bottom surface 16c) of the second recess 16B in a state of being separated from the first external electrode 13A in the drive region F1.

As illustrated in FIG. 10, the third external electrode 13C is disposed on the entire surface of each of the one end surface 11c and the other end surface 11d in the second direction D2 of the element body 11 in the element body portion 11C belonging to the non-drive region F2. The third external electrode 13C on the one end surface 11c side is electrically connected to the second internal electrodes 12B constituting the dummy electrodes 17 belonging to the first element body portion 11M on the one end surface 11c. The third external electrode 13C on the other end surface 11d side is electrically connected to the second internal electrodes 12B constituting the dummy electrodes 17 belonging to the second element body portion 11N on the other end surface 11d.

As illustrated in FIG. 10, the fourth external electrode 13D is disposed on the entire surface of the end surface 11b on the base substrate 3 side in the first direction D1 of the element body 11 and the entire surface of the inner wall surface (the first inner wall surface 16a, the second inner wall surface 16b, and the bottom surface 16c) of the second recess 16B in a state of being separated from the third external electrodes 13C in the non-drive region F2. The fourth external electrode 13D is continuous with the second external electrode 13B on the end surface 11b and the inner wall surface of the second recess 16B. The fourth external electrode 13D is electrically connected, on the first inner wall surface 16a, to the second internal electrodes 12B constituting the dummy electrodes 17 belonging to the first element body portion 11M, and is electrically connected, on the second inner wall surface 16b, to the second internal electrodes 12B constituting the dummy electrodes 17 belonging to the second element body portion 11N.

In the present embodiment, a flexible printed circuit board 18 constituting the wiring part 4 is disposed on each of the one end surface 11c side and the other end surface 11d side in the second direction D2 in the element body 11. The flexible printed circuit board 18 on the one end surface 11c side is electrically connected to each of the first external electrode 13A and the third external electrode 13C on the one end surface 11c side. The flexible printed circuit board 18 on the other end surface 11d side is electrically connected to each of the first external electrode 13A and the third external electrode 13C on the other end surface 11d side. The second external electrode 13B, which is a common electrode of the first drive units 15A and the second drive units 15B, is electrically connected to the base substrate 3 on the end surface 11b side.

Also in the piezoelectric element 2 as described above, similarly to the first embodiment, the drive units 15 can be sufficiently separated from each other in the second direction D2 and the third direction D3, and even in a case where the plurality of drive units 15 is disposed in the drive region F1 of the element body 11, it is possible to suppress interference in driving between the drive units 15. By suppressing interference in driving between the drive units 15, it is possible to suppress variations in the operation characteristics of the piezoelectric element 2.

In the present embodiment, in the element body 11, the element body portions 11A, 11B partitioned by the first recesses 16A are partitioned by the bottomed second recess 16B extending in the third direction D3 into the first element body portion 11M in which the first drive unit 15A is located and the second element body portion 11N in which the second drive unit 15B is located. According to such a configuration, the first drive unit 15A and the second drive unit 15B can be physically separated in both the second direction D2 and the third direction D3 by the first recesses 16A and the second recess 16B. Therefore, it is possible to more effectively suppress interference in driving between the drive units 15. In addition, since the second recess 16B is bottomed, displacement of the element body 11 can be restrained at the bottom part of the second recess 16B.

In the present embodiment, the first external electrode 13A electrically connected to the first internal electrodes 12A of the first drive unit 15A is located on the one end surface 11c in the second direction D2 of the element body 11, and the first external electrode 13A electrically connected to the first internal electrodes 12A of the second drive unit 15B is located on the other end surface 11d in the second direction D2 of the element body 11. In addition, the second external electrode 13B electrically connected to the second internal electrodes 12B of the first drive unit 15A and the second internal electrodes 12B of the second drive unit 15B is located on the inner wall surface of the second recess 16B and the end surface 11b in the first direction D1 of the element body 11 continuous with the inner wall surface. According to such a configuration, even in a case where the first drive unit 15A and the second drive unit 15B are physically separated in both the second direction D2 and the third direction D3 by the first recesses 16A and the second recess 16B, the wiring part 4 can be connected to the first external electrode 13A and the second external electrode 13B with a simple configuration.

What is claimed is:

1. A piezoelectric element comprising:
an element body configured by a plurality of piezoelectric layers stacked in a first direction, the element body having a predetermined width in a second direction orthogonal to the first direction and extending in a third direction orthogonal to the first direction and the second direction, wherein
the element body contains a drive region in which a drive unit is disposed, the drive unit including a first internal electrode and a second internal electrode facing each other in the first direction with the plurality of piezoelectric layers interposed between the first internal electrode and the second internal electrode, and the element body has a first external electrode electrically connected to the first internal electrode and a second external electrode electrically connected to the second internal electrode,
the drive unit has a plurality of first drive units arranged in the third direction on one side in the second direction and a plurality of second drive units arranged in the third direction on another side in the second direction, and
the plurality of first drive units and the plurality of second drive units are alternately disposed in the third direction in a case where the element body is viewed from the first direction.

2. The piezoelectric element according to claim 1, wherein the plurality of first drive units and the plurality of second drive units are disposed in a staggered manner in a case where the element body is viewed from the first direction.

3. The piezoelectric element according to claim 1, wherein the plurality of first drive units and the plurality of second drive units are separated in the second direction in a case where the element body is viewed from the third direction.

4. The piezoelectric element according to claim 1, wherein a non-drive region in which neither the plurality of first drive units nor the plurality of second drive units is disposed is provided at an end part in the third direction of the element body, and
a dummy electrode formed by the first internal electrode or the second internal electrode is disposed in the non-drive region.

5. A drive device comprising:
the piezoelectric element according to claim 1; and
a wiring part electrically connected to the first external electrode and the second external electrode.

6. The drive device according to claim 5, wherein
the element body has a plurality of bottomed first recesses extending in the second direction, and
the plurality of first drive units and the plurality of second drive units alternately disposed in the third direction are partitioned by the plurality of bottomed first recesses.

7. The drive device according to claim 6, wherein in the element body, an element body portion partitioned by the plurality of bottomed first recesses is continuous in the second direction.

8. The drive device according to claim 6, wherein in the element body, an element body portion partitioned by the plurality of bottomed first recesses is partitioned by a bottomed second recess extending in the third direction into a first element body portion in which one of the plurality of first drive units is located and a second element body portion in which one of the plurality of second drive units is located.

9. The drive device according to claim 8, wherein
the first external electrode electrically connected to the first internal electrode of one of the plurality of first drive units is located on one end surface in the second direction of the element body,
the first external electrode electrically connected to the first internal electrode of one of the plurality of second drive units is located on another end surface in the second direction of the element body, and
the second external electrode electrically connected to a plurality of the second internal electrode of the plurality of first drive units and a plurality of the second internal electrode of the plurality of second drive units is located on an inner wall surface of the bottomed second recess and an end surface in the first direction of the element body continuous with the inner wall surface.

10. The drive device according to claim 5, further comprising:
a base substrate electrically connected to the second external electrode.
